(19) United States
(12) Patent Application Publication
(10) Pub. No.: US 2025/0374586 A1
(43) Pub. Date: Dec. 4, 2025

(54) SEMICONDUCTOR DEVICE

(71) Applicant: KABUSHIKI KAISHA TOSHIBA, Tokyo (JP)

(72) Inventors: Yosuke KAJIWARA, Yokohama (JP); Masahiko KURAGUCHI, Yokohama (JP)

(73) Assignee: KABUSHIKI KAISHA TOSHIBA, Tokyo (JP)

(21) Appl. No.: 19/297,024

(22) Filed: Aug. 12, 2025

Related U.S. Application Data
(62) Division of application No. 17/652,124, filed on Feb. 23, 2022.

(30) Foreign Application Priority Data
Jul. 1, 2021 (JP) 2021-109813
Jan. 11, 2022 (JP) 2022-001999

(51) Int. Cl. H10D 30/47; H10D 62/85

(52) U.S. Cl. CPC H10D 30/47; H10D 62/8503

(57) ABSTRACT

According to one embodiment, a semiconductor device includes first to third electrodes, a semiconductor member, and a first insulating member. The third electrode is between the first and second electrodes. The semiconductor member includes first and second semiconductor regions. The first semiconductor region includes first to fifth partial regions. The fourth partial region is between the first and third partial regions. The fifth partial region is between the third and second partial regions. The second semiconductor region includes first and second semiconductor portions. The first insulating member includes first to third insulating regions. The fourth partial region includes a first facing region. The fifth partial region includes a second facing region. The first facing region includes a first element. The second facing region does not include the first element, or a concentration of the first element in the second facing region is lower than in the first facing region.

### CROSS-REFERENCE TO RELATED APPLICATIONS

This application is a division of and claims benefit under 35 U.S.C. § 120 to U.S. application Ser. No. 17/652,124, filed Feb. 23, 2022, which is based upon and claims the benefit of priority under 35 U.S.C. § 119 from Japanese Patent Application No.2021-109813, filed on Jul. 1, 2021, and Japanese Patent Application No.2022-1999, filed on Jan. 11, 2022; the entire contents of which are incorporated herein by reference.

### FIELD

Embodiments described herein generally relate to a semiconductor device.

### BACKGROUND

Improvement of characteristics is desired in semiconductor devices.

### BRIEF DESCRIPTION OF THE DRAWINGS

FIG. 1 is a schematic cross-sectional view illustrating a semiconductor device according to the first embodiment;

FIG. 2 is a graph illustrating the characteristics of the semiconductor device;

FIG. 3 is a schematic cross-sectional view illustrating a semiconductor device according to the first embodiment;

FIG. 4 is a schematic cross-sectional view illustrating a semiconductor device according to the first embodiment;

FIG. 5 is a schematic cross-sectional view illustrating a semiconductor device according to the first embodiment;

FIG. 6 is a schematic cross-sectional view illustrating a semiconductor device according to the first embodiment;

FIG. 7 is a schematic cross-sectional view illustrating a semiconductor device according to the first embodiment;

FIG. 8 is a schematic cross-sectional view illustrating a semiconductor device according to the first embodiment;

FIG. 9 is a schematic cross-sectional view illustrating a semiconductor device according to the first embodiment;

FIG. 10 is a schematic cross-sectional view illustrating a semiconductor device according to the first embodiment;

FIG. 11 is a schematic cross-sectional view illustrating a semiconductor device according to the first embodiment;

FIG. 12 is a schematic cross-sectional view illustrating a semiconductor device according to the first embodiment; and

FIG. 13 is a schematic cross-sectional view illustrating a semiconductor device according to a second embodiment.

### DETAILED DESCRIPTION

According to one embodiment, a semiconductor device includes a first electrode, a second electrode, a third electrode, a semiconductor member, and a first insulating member. A direction from the first electrode to the second electrode is along the first direction. A position of the third electrode in the first direction is between a position of the first electrode in the first direction and a position of the second electrode in the first direction. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, and a fifth partial region. A direction from the first partial region to the first electrode is along a second direction crossing the first direction. A direction from the second partial region to the second electrode is along the second direction. A direction from the third partial region to the third electrode is along the second direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. The second semiconductor region includes Alₓ₂Ga₁₋ₓ₂N (0<x2≤1, x1<x2). The second semiconductor region includes a first semiconductor portion, and a second semiconductor portion. A direction from the fourth partial region to the first semiconductor portion is along the second direction. A direction from the fifth partial region to the second semiconductor portion is along the second direction. The first insulating member includes a first insulating region, a second insulating region, and a third insulating region. The first insulating region is between the fourth partial region and the third electrode in the first direction. The second insulating region is between the third electrode and the fifth electrode in the first direction. The third insulating region is between the third partial region and the third electrode in the second direction. The fourth partial region includes a first facing region. The first facing region is in contact with the first insulating region. The fifth partial region includes a second facing region. The second facing region is in contact with the second insulating region. The first facing region includes a first element. The first element includes at least one selected form the group consisting of Si, Ge, Te and Sn. The second facing region does not include the first element, or a concentration of the first element in the second facing region is lower than a concentration of the first element in the first facing region.

According to one embodiment, a semiconductor device includes a first electrode, a second electrode, a third electrode, a semiconductor member, a first insulating member, and a compound member. A direction from the first electrode to the second electrode is along the first direction. A position of the third electrode in the first direction is between a position of the first electrode in the first direction and a position of the second electrode in the first direction. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, and a fifth partial region. A direction from the first partial region to the first electrode is along a second direction crossing the first direction. A direction from the second partial region to the second electrode is along the second direction. A direction from the third partial region to the third electrode is along the second direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. The second semiconductor region includes Alₓ₂Ga₁₋ₓ₂N (0<x2≤1, x1<x2). The second semiconductor region includes a first semiconductor portion, and a second semiconductor portion. A direction from the fourth partial region to the first semiconductor portion is along the second direction. A direction from the fifth partial region to the second semiconductor portion is along the second direction. The first insulating member includes a first insulating region, a second insulating region, and a third insulating region. The first insulating region is between the fourth partial region and the third electrode in the first direction. The second insulating region is between the third electrode and the fifth electrode in the first direction. The third insulating region is between the third partial region and the third electrode in the second direction. The compound member includes Alₓ₃Ga₁₋ₓ₃N (0<x3≤1, x2≤x3). The compound member includes a first compound region and a second compound region. The first compound region is between the fourth partial region and the first insulating region in the first direction. The second compound region is between the second insulating region and the fifth partial region in the first direction.

The fourth partial region includes a first facing region. The first facing region is in contact with the first compound region. The fifth partial region includes a second facing region. The second facing region is in contact with the second compound region. The first facing region includes a first element. The first element includes at least one selected by the group consisting of Si, Ge, Te and Sn. The second facing region does not include the first element, or a concentration of the first element in the second facing region is lower than a concentration of the first element in the first facing region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

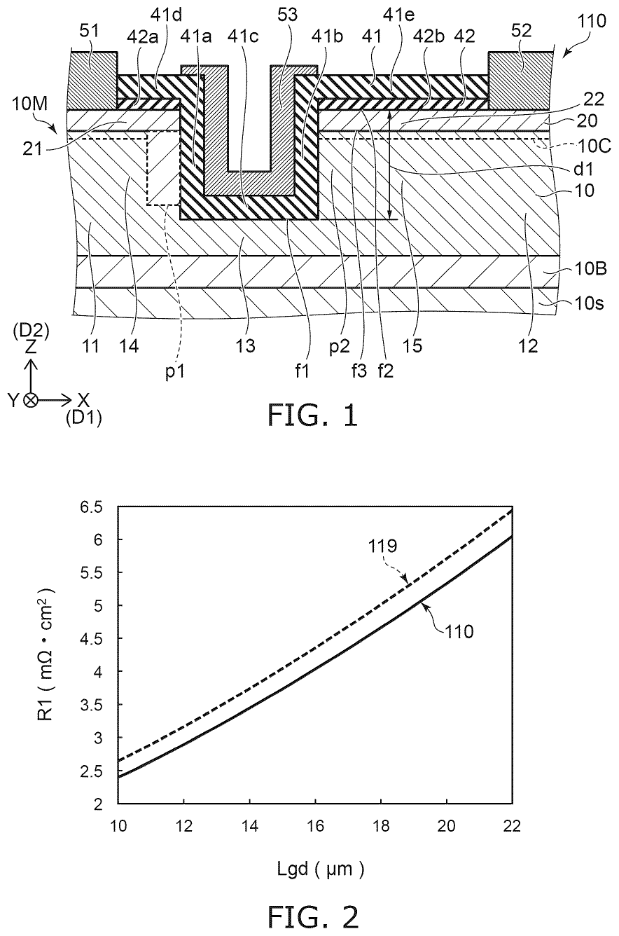

FIG. 1 is a schematic cross-sectional view illustrating a semiconductor device according to a first embodiment.

As shown in FIG. 1, the semiconductor device 110 according to the embodiment includes a first electrode 51, a second electrode 52, a third electrode 53, a semiconductor member 10M, and a first insulating member 41.

A direction from the first electrode 51 to the second electrode 52 is along a first direction D1. The first direction D1 is an X-axis direction. One direction perpendicular to the X-axis direction is defined as the Z-axis direction. The direction perpendicular to the X-axis direction and the Z-axis direction is defined as the Y-axis direction.

A position of the third electrode 53 in the first direction D1 is between a position of the first electrode 51 in the first direction D1 and a position of the second electrode 52 in the first direction D1. For example, at least a part of the third electrode 53 is between the first electrode 51 and the second electrode 52 in the first direction D1.

The semiconductor member 10M includes a first semiconductor region 10 and a second semiconductor region 20.

The first semiconductor region 10 includes Alₓ₁Ga₁₋ₓ₁N (0≤x1<1). In one example, the composition ratio x1 is not less than 0 and less than 0.1. The first semiconductor region 10 is, for example, a GaN layer.

The first semiconductor region 10 includes a first partial region 11, a second partial region 12, a third partial region 13, a fourth partial region 14, and a fifth partial region 15. A direction from the first partial region 11 to the first electrode 51 is along the second direction D2. The second direction D2 crosses the first direction D1. A direction from the second partial region 12 to the second electrode 52 is along the second direction D2. A direction from the third partial region 13 to at least a part of the third electrode 53 is along the second direction D2. For example, in the second direction D2, a region overlaps the first electrode 51 corresponds to the first partial region 11. For example, in the second direction D2, a region overlaps the second electrode 52 corresponds to the second partial region 12. For example, in the second direction D2, a region overlaps at least a part of the third electrode 53 corresponds to the third partial region 13.

A position of the fourth partial region 14 in the first direction D1 is between the position of the first partial region 11 in the first direction D1 and the position of the third partial region 13 in the first direction D1. A position of the fifth partial region 15 in the first direction D1 is between the position of the third partial region 13 in the first direction D1 and the position of the second partial region 12 in the first direction D1. The boundaries between these partial regions may be unclear.

The second semiconductor region 20 includes Alₓ₂Ga₁₋ₓ₂N (0<x2≤1, x1<x2). In one example, the composition ratio x2 is not less than 0.1 and not more than 0.3. The second semiconductor region 20 is, for example, an AlGaN layer. An AlN layer may be provided between the first semiconductor region 10 and the second semiconductor region 20. The thickness of the AlN layer is, for example, not more than 3 nm.

The second semiconductor region 20 includes a first semiconductor portion 21 and a second semiconductor portion 22. A direction from the fourth partial region 14 to the first semiconductor portion 21 is along the second direction D2. A direction from the fifth partial region 15 to the second semiconductor portion 22 is along the second direction D2.

The first insulating member 41 includes a first insulating region 41a, a second insulating region 41b, and a third insulating region 41c. The first insulating region 41a is between the fourth partial region 14 and the third electrode 53 in the first direction D1. The second insulating region 41b is between the third electrode 53 and the fifth partial region 15 in the first direction D1. The third insulating region 41c is between the third partial region 13 and the third electrode 53 in the second direction D2.

The fourth partial region 14 includes a first facing region p1. The first facing region p1 is in contact with the first insulating region 41a. The fifth partial region 15 includes a second facing region p2. The second facing region p2 is in contact with the second insulating region 41b.

The first facing region p1 includes a first element. The first element includes at least one selected from the group consisting of Si, Ge, Te and Sn. The first facing region p1 is, for example, an n-type region. The second facing region p2 does not include the first element. Alternatively, a concentration of the first element in the second facing region p2 is lower than a concentration of the first element in the first facing region p1. The second facing region p2 is, for example, an undoped region.

As shown in FIG. 1, the semiconductor device 110 may include a base body 10s and a nitride semiconductor layer 10B. The base body 10s may be, for example, a silicon substrate or a SiC substrate. The nitride semiconductor layer 10B is provided on the base body 10s. The nitride semiconductor layer 10B includes, for example, Al and N. The nitride semiconductor layer 10B may include an AlGaN layer. The first semiconductor region 10 is provided on the nitride semiconductor layer 10B. The second semiconductor region 20 is provided on the first semiconductor region 10.

A current flowing between the first electrode 51 and the second electrode 52 can be controlled by a potential of the third electrode 53. The potential of the third electrode 53 may be, for example, a value based on a potential of the first electrode 51. The first electrode 51 functions as one of a source electrode and a drain electrode. The second electrode 52 functions as the other of the source electrode and the drain electrode. The third electrode 53 functions as, for example, a gate electrode. The semiconductor device 110 is, for example, a transistor.

In this example, a distance along the first direction D1 between the first electrode 51 and the third electrode 53 is shorter than a distance along the first direction D1 between the third electrode 53 and the second electrode 52. The first electrode 51 functions as a source electrode, and the second electrode 52 functions as a drain electrode.

The first semiconductor region 10 includes a region facing the second semiconductor region 20. A carrier region 10C is formed in this region. The carrier region 10C is, for example, a two-dimensional electron gas. The semiconductor device 110 is, for example, HEMT (High Electron Mobility Transistor).

As described above, the first insulating region 41a is between the fourth partial region 14 and the third electrode 53 in the first direction D1. The second insulating region 41b is between the third electrode 53 and the fifth partial region 15 in the first direction D1. In this case, the third electrode 53 is between the fourth partial region 14 and the fifth partial region 15 in the first direction D1. The third electrode 53 is a recess type gate electrode. As a result, a high threshold voltage can be obtained.

As described above, in the embodiment, the n-type region is provided asymmetrically. This provides a low ON-resistance in addition to a high threshold voltage. It is possible to provide a semiconductor device whose characteristics can be improved.

For example, there is a first reference example in which an n-type region is not provided. In the first reference example, a high threshold voltage would be obtained. However, in the first reference example, the ON-resistance is high.

When a structure for increasing the threshold voltage is provided in at least a part of the current path from the first electrode 51 to the second electrode 52, a high threshold voltage can be obtained. In the semiconductor device 110, the recess type gate electrode increases the threshold voltage in the region between the third electrode 53 and the second electrode 52. On the other hand, an n-type region is provided between the first electrode 51 and the third electrode 53. This provides a low ON-resistance.

As shown in FIG. 1, the third partial region 13 includes a first surface f1. The first surface f1 faces the third insulating region 41c. The second semiconductor portion 22 includes a second surface f2 and a third surface f3. The third surface f3 faces the fifth partial region 15. The second surface f2 is on the opposite side of the third surface f3 in the second direction D2. For example, the third surface f3 is between the fifth partial region 15 and the second surface f2 in the second direction D2.

A distance along the second direction D2 between the first surface f1 and the second surface f2 is defined as a distance d1. The distance d1 corresponds to, for example, the recess depth. In the embodiment, the distance d1 is preferably, for example, not less than 100 nm and not more than 400 nm. When the distance d1 is 100 nm or more, an appropriately high threshold voltage can be obtained. For example, the normally-off characteristic can be stably obtained. When the distance d1 is 400 nm or less, it is easy to obtain a low ON-resistance.

As shown in FIG. 1, the first insulating member 41 may include a fourth insulating region 41d and a fifth insulating region 41e. The first semiconductor portion 21 is between the fourth partial region 14 and the fourth insulating region 41d. The second semiconductor portion 22 is between the fifth partial region 15 and the fifth insulating region 41e. The boundaries between the first to fifth insulating regions 41a to 41e may be unclear.

In one example, the first insulating member 41 includes silicon and oxygen. The first insulating member 41 includes silicon oxide (for example, SiO₂). The first insulating member 41 may include at least one selected from the group consisting of silicon and aluminum and at least one selected from the group consisting of oxygen and nitrogen.

As shown in FIG. 1, the semiconductor device 110 may include a second insulating member 42. The second insulating member 42 includes silicon and nitrogen in one example. The second insulating member 42 includes, for example, SiN. The second insulating member 42 includes a first insulating portion 42a and a second insulating portion 42b. The first semiconductor portion 21 is between the fourth partial region 14 and the first insulating portion 42a in the second direction D2. The second semiconductor portion 22 is between the fifth partial region 15 and the second insulating portion 42b in the second direction D2.

For example, the first insulating portion 42a is between the first semiconductor portion 21 and the fourth insulating region 41d. For example, the second insulating portion 42b is between the second semiconductor portion 22 and the fifth insulating region 41e. For example, the first insulating portion 42a may be in contact with the first semiconductor portion 21. For example, the second insulating portion 42b may be in contact with the second semiconductor portion 22. By providing the second insulating member 42, stable characteristics can be easily obtained in the second semiconductor region 20. For example, current collapse can be suppressed.

FIG. 2 is a graph illustrating the characteristics of the semiconductor device.

FIG. 2 illustrates a result of simulating the characteristic ON-resistance when the gate-drain distance is changed in the semiconductor device. The horizontal axis of FIG. 2 is the gate-drain distance Lgd. The gate-drain distance Lgd corresponds to a distance along the first direction D1 between the third electrode 53 and the second electrode 52. The vertical axis of FIG. 2 is the characteristic ON-resistance R1. FIG. 2 shows the characteristics of the semiconductor device 110 and the characteristics of the semiconductor device 119 of the first reference example. As shown in FIG. 2, in the same gate-drain distance Lgd, the semiconductor device 110 can obtain a characteristic ON-resistance R1 lower than that in the semiconductor device 119.

The semiconductor device 110 can be manufactured, for example, as follows. For example, a stacked body to be the first semiconductor region 10 and the second semiconductor region 20 including the n-type region is prepared. The n-type region can be formed by, for example, ion implantation. A recess is formed in the stacked body. After that, an insulating film is formed in the recess. The third electrode 53 is formed by filling the remaining space of the recess with the conductive material. The semiconductor device 110 is obtained by forming the first electrode 51 and the second electrode 52.

In another example, a recess is formed in the stacked body that does not include the n-type region. After that, an n-type region is formed in a part of the first semiconductor region 10. The n-type region can be formed by, for example, ion implantation. After that, an insulating film is formed, and the first to third electrodes 51 to 53 are formed. The semiconductor device 110 can also be formed by such a method.

In the embodiment, the concentration of the first element in the first facing region p1 is not less than 1×10¹⁶ cm⁻³ and not more than 5×10¹⁹ cm⁻³.

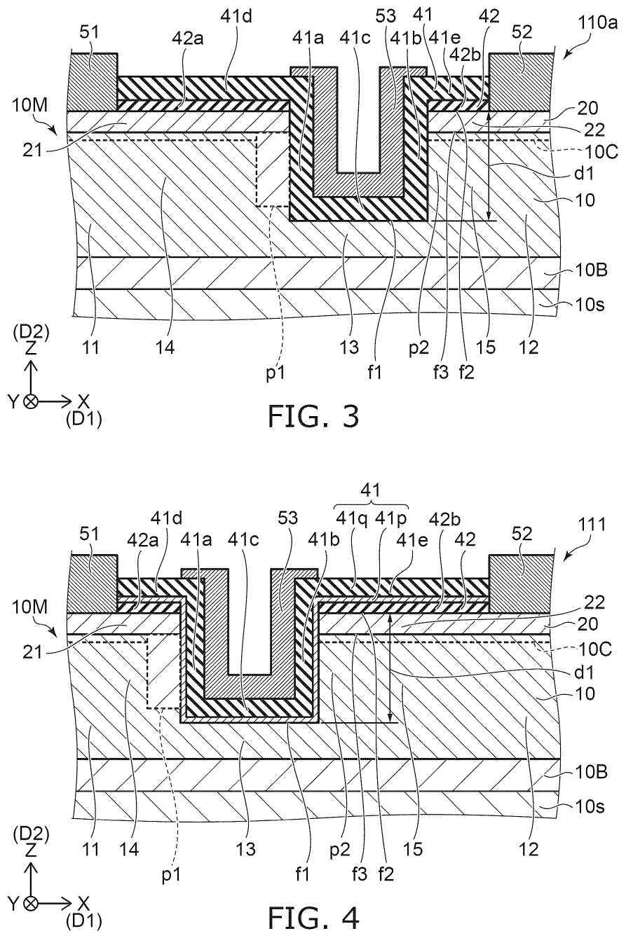

FIG. 3 is a schematic cross-sectional view illustrating a semiconductor device according to the first embodiment.

As shown in FIG. 3, in a semiconductor device 110a according to the embodiment, the position of the third electrode 53 is different from the position of the third electrode 53 in the semiconductor device 110. Other configurations in the semiconductor device 110a may be the same as those in the semiconductor device 110.

In the semiconductor device 110a, the distance along the first direction D1 between the first electrode 51 and the third electrode 53 is longer than the distance along the first direction D1 between the third electrode 53 and the second electrode 52. In the semiconductor device 110a, the first electrode 51 functions as a drain electrode, and the second electrode 52 functions as a source electrode. The semiconductor device 110a is also provided with the first facing region p1 of n-type. This provides a high threshold voltage and a low on-resistance. It is possible to provide a semiconductor device whose characteristics can be improved.

Various configurations described below can be applied to the semiconductor device 110 and the semiconductor device 110a.

FIG. 4 is a schematic cross-sectional view illustrating a semiconductor device according to the first embodiment.

As shown in FIG. 4, in a semiconductor device 111 according to the embodiment, the first insulating member 41 includes a plurality of films (a first film 41p, a second film 41q, etc.). Other configurations in the semiconductor device 111 may be the same as those in the semiconductor device 110 or the semiconductor device 110a.

In the semiconductor device 111, the first insulating member 41 includes the first film 41p and the second film 41q. The first film 41p is provided between the second film 41q and the semiconductor member 10M. Such a first film 41p and a second film 41q may be provided in each of the first to fifth insulating regions 41a to 41e.

The material of the first film 41p is different from the material of the second film 41q. For example, the first film 41p includes Alₓ₃Ga₁₋ₓ₃N (0<x3≤1, x2≤x3). The first film 41p is, for example, an AlN film. The second film 41q includes silicon and oxygen.

By providing the first film 41p as described above, the characteristics of the semiconductor member 10M tend to be stable. For example, by providing the first film 41p as described above, high mobility can be easily obtained. The ON-resistance of the device can be lowered. By providing the second film 41q as described above, for example, a stable threshold voltage can be easily obtained.

For example, a high reliability can be obtained.

When the second film 41q including silicon and oxygen is provided, for example, the second film 41q does not have to include nitrogen. Alternatively, a concentration of nitrogen included in the second film 41q may be lower than a concentration of nitrogen included in the second insulating member 42. Higher reliability can be obtained.

The second insulating member 42 does not include oxygen, for example. Alternatively, a concentration of oxygen included in the second insulating member 42 may be lower than a concentration of oxygen included in the second film 41q.

The above-mentioned second film 41q may be included in the first insulating member 41, and the first film 41p may be considered to be provided separately from the first insulating member 41. Hereinafter, such an example will be described.

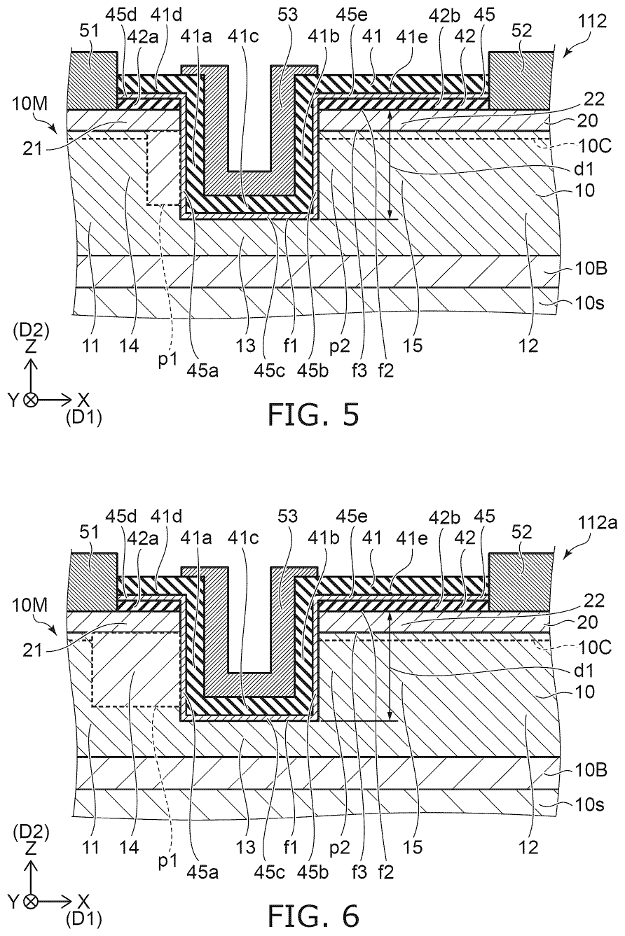

FIG. 5 is a schematic cross-sectional view illustrating a semiconductor device according to the first embodiment.

As shown in FIG. 5, a semiconductor device 112 according to the embodiment includes the first to third electrodes 51 to 53, the semiconductor member 10M, the first insulating member 41, and the compound member 45. The first insulating member 41 in the semiconductor device 112 corresponds to the second film 41q in the semiconductor device 111. The compound member 45 corresponds to the first film 41p in the semiconductor device 111. Other configurations in the semiconductor device 112 may be the same as those in the semiconductor device 110 or the semiconductor device 111.

For example, the first insulating member 41 includes the first to third insulating regions 41a to 41c. The first insulating region 41a is between the fourth partial region 14 and the third electrode 53 in the first direction D1. The second insulating region 41b is between the third electrode 53 and the fifth partial region 15 in the first direction D1. The third insulating region 41c is between the third partial region 13 and the third electrode 53 in the second direction D2.

The compound member 45 includes Alₓ₃Ga₁₋ₓ₃N (0<x3≤1, x2≤x3). The compound member 45 is, for example, an AlN film. The compound member 45 includes a first compound region 45a and a second compound region 45b. The first compound region 45a is between the fourth partial region 14 and the first insulating region 41a in the first direction D1. The second compound region 45b is between the second insulating region 41b and the fifth partial region 15 in the first direction D1.

The fourth partial region 14 includes the first facing region The first facing region p1 is in contact with the first p1. compound region 45a. The fifth partial region 15 includes the second facing region p2. The second facing region p2 is in contact with the second compound region 45b.

The first facing region p1 includes the first element. The first element includes at least one of Si, Ge, Te and Sn. The second facing region p2 does not include the first element. Alternatively, the concentration of the first element in the second facing region p2 is lower than the concentration of the first element in the first facing region p1. Even in the semiconductor device 112, high mobility can be easily obtained by providing the compound member 45. The ON-resistance of the device can be lowered.

The compound member 45 may include a third compound region 45c. The third compound region 45c is between the third partial region 13 and the third insulating region 41c in the second direction D2. At least one of the first compound region 45a, the second compound region 45b, and the third compound region 45c may be a single crystal. Due to the single crystal, it is easy to obtain higher mobility. The ON-resistance of the device can be lowered.

The semiconductor device 112 may include the second insulating member 42. The second insulating member 42 includes silicon and nitrogen. The second insulating member 42 includes a first insulating portion 42a and a second insulating portion 42b. The first semiconductor portion 21 is between the fourth partial region 14 and the first insulating portion 42a in the second direction D2. The second semiconductor portion 22 is between the fifth partial region 15 and the second insulating portion 42b in the second direction D2.

In the semiconductor device 112, the first insulating member 41 includes, for example, silicon and oxygen. The first insulating member 41 does not include nitrogen. Alternatively, the concentration of nitrogen included in the first insulating member 41 is lower than the concentration of nitrogen included in the second insulating member 42. For example, the second insulating member 42 does not include oxygen. Alternatively, the concentration of oxygen included in the second insulating member 42 is lower than the concentration of oxygen included in the first insulating member 41.

Higher reliability can be obtained by providing the first insulating member 41 including silicon and oxygen.

In the semiconductor device 112, the compound member 45 may include a fourth compound region 45d and a fifth compound region 45e. The first insulating portion 42a is between the first semiconductor portion 21 and the fourth compound region 45d. The second insulating portion 42b is between the second semiconductor portion 22 and the fifth compound region 45e.

The first insulating member 41 may include a fourth insulating region 41d and a fifth insulating region 41e. The fourth compound region 45d is between the first semiconductor portion 21 and the fourth insulating region 41d. The fifth compound region 45e is between the second semiconductor portion 22 and the fifth insulating region 41e.

FIG. 6 is a schematic cross-sectional view illustrating a semiconductor device according to the first embodiment.

As shown in FIG. 6, in a semiconductor device 112a according to the embodiment, a part of the first facing region p1 including the first element overlaps a part of the first electrode 51 in the second direction D2. The configuration other than these in the semiconductor device 112a may be the same as the configuration in the semiconductor device 112. Also in the semiconductor device 112a, a high threshold voltage and a low ON-resistance can be obtained. It is possible to provide a semiconductor device whose characteristics can be improved.

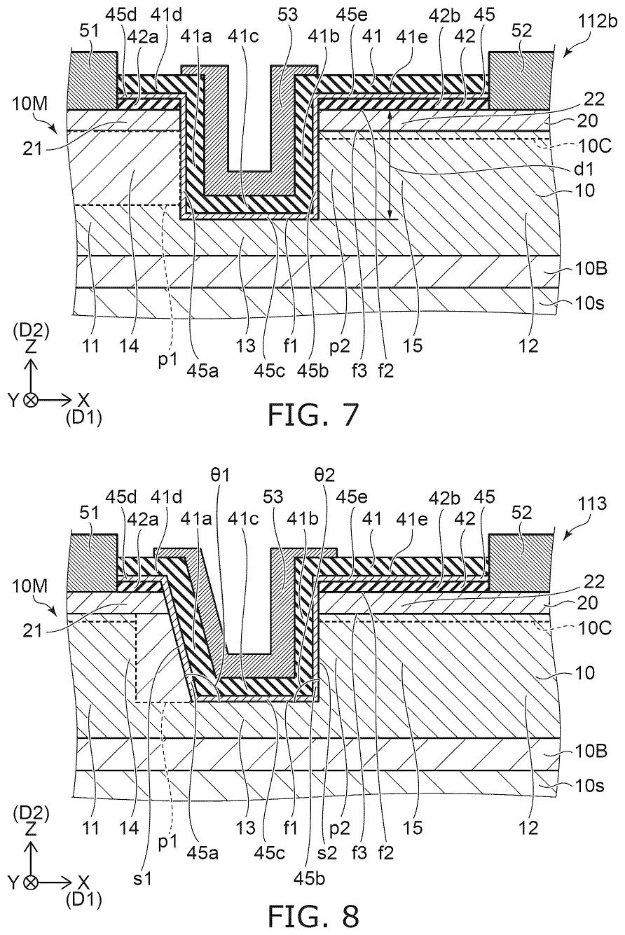

FIG. 7 is a schematic cross-sectional view illustrating a semiconductor device according to the first embodiment.

As shown in FIG. 7, in a semiconductor device 112b according to the embodiment, a part of the first facing region p1 including the first element overlaps the first electrode 51 in the second direction D2. For example, the first partial region 11 includes the first element. The configurations other than these in the semiconductor device 112b may be the same as the configurations in the semiconductor device 112. Also in the semiconductor device 112b, a high threshold voltage and a low ON-resistance can be obtained. It is possible to provide a semiconductor device whose characteristics can be improved. A part of the first facing region p1 including the first element overlaps the first electrode 51 in the second direction D2. Thereby, for example, the contact resistance between the first electrode 51 and the first semiconductor portion 21 can be lowered. A low ON-resistance is obtained.

FIG. 8 is a schematic cross-sectional view illustrating a semiconductor device according to the first embodiment.

As shown in FIG. 8, in a semiconductor device 113 according to the embodiment, the third partial region 13 includes the first surface f1. The first surface f1 faces the third insulating region 41c in the second direction D2. The fourth partial region 14 includes a first side surface s1. The first side surface s1 faces the first insulating region 41a in the first direction D1. The fifth partial region 15 includes a second side surface s2. The second side surface s2 faces the second insulating region 41b in the first direction D1.

An angle between the first surface f1 and the first side surface s1 is defined as a first angle θ1. The angle between the first surface f1 and the second side surface s2 is defined as a second angle θ2. The first angle θ1 is larger than the second angle θ2. The first angle θ1 is, for example, greater than 90 degrees. Since the first angle θ1 is large, for example, a low ON-resistance can be easily obtained. High reliability is easy to obtain.

For example, an absolute value of a difference between the second angle θ2 and 90 degrees is smaller than an absolute value of a difference between the first angle θ1 and 90 degrees. The second angle θ2 is close to 90 degrees. Due to such a second angle θ2, a high threshold voltage can be easily obtained. The second angle θ2 may be less than 90 degrees. It is easy to obtain a higher threshold voltage.

The configuration of the semiconductor device 113 excluding the above angle difference may be the same as the configuration of the semiconductor device 112.

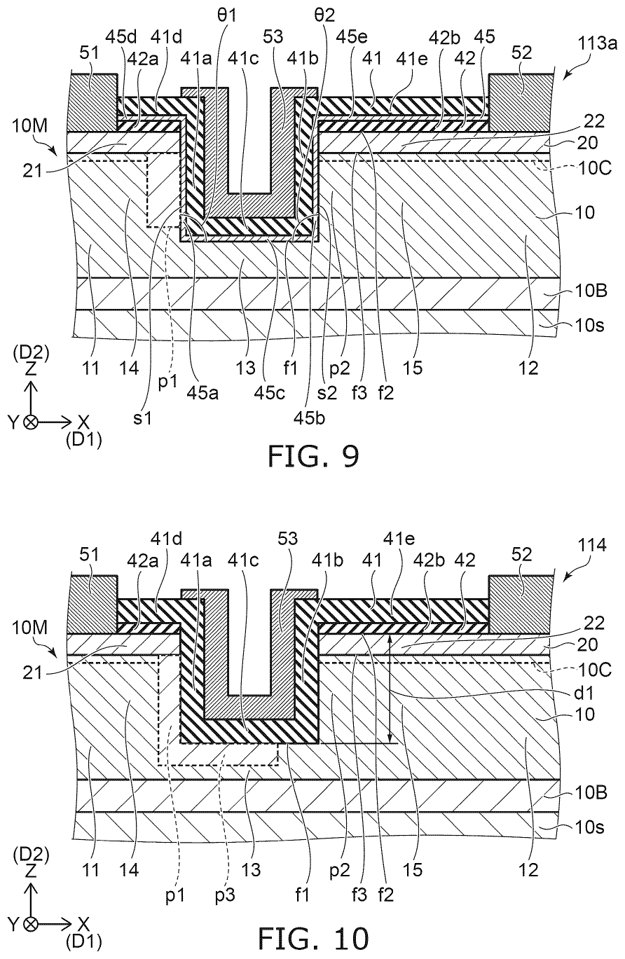

FIG. 9 is a schematic cross-sectional view illustrating a semiconductor device according to the first embodiment.

As shown in FIG. 9, in a semiconductor device 113a according to the embodiment, the third partial region 13 includes the first surface f1. The fourth partial region 14 includes the first side surface s1. The fifth partial region 15 includes the second side surface s2. The second angle θ2 between the first surface f1 and the second side surface s2 is, for example, not less than 70 degrees and not more than 110 degrees. Since the second angle θ2 is close to 90 degrees, it is easy to obtain a high threshold voltage. The second angle θ2 may be less than 90 degrees. It is easy to obtain a higher threshold voltage.

FIG. 10 is a schematic cross-sectional view illustrating a semiconductor device according to the first embodiment.

As shown in FIG. 10, in a semiconductor device 114 according to the embodiment, the third partial region 13 includes a region p3. The third facing region p3 is in contact with the third insulating region 41c. At least a part of the third facing region p3 includes the first element. The configuration of the semiconductor device 114 other than the above may be the same as the configuration of the semiconductor device 110 or the semiconductor device 111.

In the semiconductor device 114, the third facing region p3 is an n-type region. As described above, in addition to the first facing region p1 of n-type, the third facing region p3 of n-type may be provided.

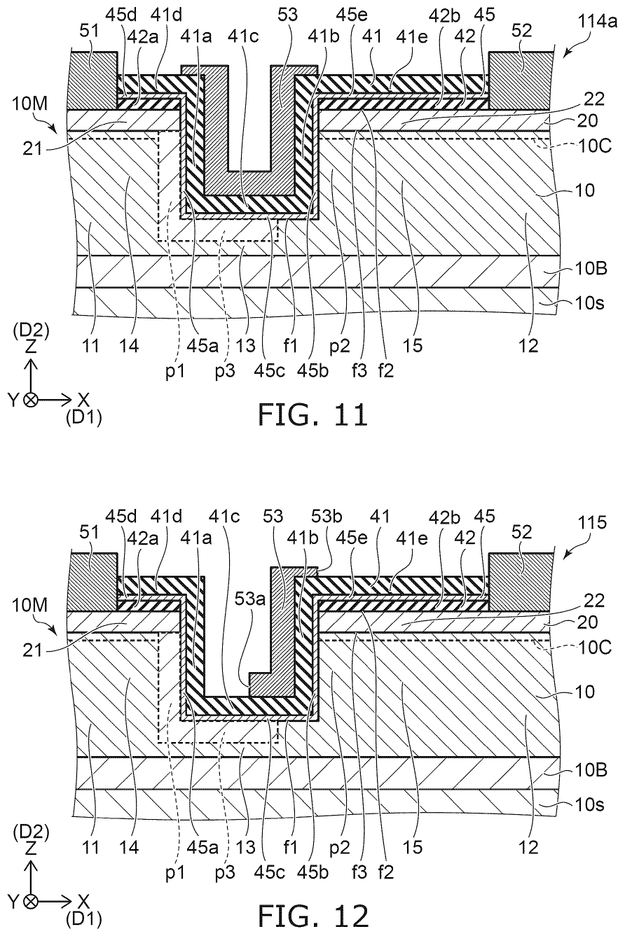

FIG. 11 is a schematic cross-sectional view illustrating a semiconductor device according to the first embodiment.

As shown in FIG. 11, the compound member 45 is provided in a semiconductor device 114a according to the embodiment. The third partial region 13 includes the third facing region p3. The third facing region p3 is in contact with the third compound region 45c. At least a part of the third facing region p3 includes the first element. The configuration of the semiconductor device 114a other than the above may be the same as the configuration of the semiconductor device 112.

In the semiconductor device 114a, the third facing region p3 is an n-type region. As described above, in addition to the first facing region p1 of n-type, the third facing region p3 of n-type may be provided.

In the semiconductor device 114 and the semiconductor device 114a, a high threshold voltage and a low ON-resistance can be obtained. It is possible to provide a semiconductor device whose characteristics can be improved.

FIG. 12 is a schematic cross-sectional view illustrating a semiconductor device according to the first embodiment.

As shown in FIG. 12, in a semiconductor device 115 according to the embodiment, the shape of the third electrode 53 is different from the shape of the third electrode 53 in the semiconductor device 112. The configuration of the semiconductor device 115 other than the above may be the same as the configuration of the semiconductor device 112.

In the semiconductor device 115, the third electrode 53 includes a first end portion 53a and a second end portion 53b. The first end portion 53a is an end portion on the side of the first electrode 51. The second end portion 53b is an end portion on the side of the second electrode 52.

A position of the first end portion 53a in the first direction D1 is between the position of the first electrode 51 in the first direction D1 and a position of the second end portion 53b in the first direction D1. The position of the second end portion 53b in the first direction D1 is between the position of the first end portion 53a in the first direction D1 and the position of the second electrode 52 in the first direction D1.

The first end portion 53a is between the fourth partial region 14 and the fifth partial region 15 in the first direction D1. A position of the second semiconductor portion 22 in the second direction D2 is between a position of the first end portion 53a in the second direction D2 and a position of the second end portion 53b in the second direction D2.

Even when such a shape is provided, a high threshold voltage and a low on-resistance can be obtained. It is possible to provide a semiconductor device whose characteristics can be improved. The third electrode 53 having such a shape may be applied to the semiconductor device 110 or the semiconductor device 111.

### Second Embodiment

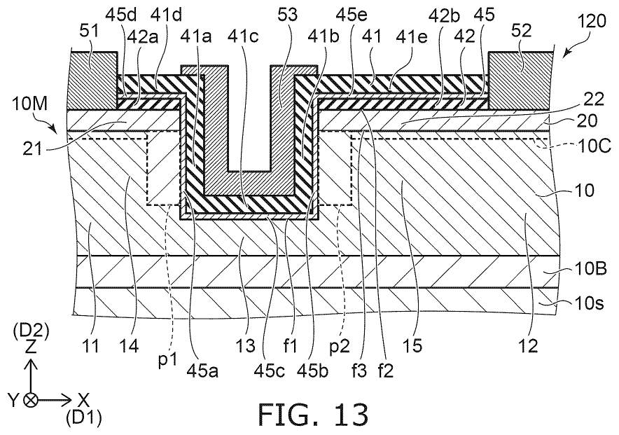

FIG. 13 is a schematic cross-sectional view illustrating a semiconductor device according to a second embodiment.

As shown in FIG. 13, in a semiconductor device 120 according to the embodiment, the second facing region p2 is of a p-type. The configuration of the semiconductor device 120 other than the above may be the same as the configuration of any semiconductor device according to the first embodiment.

In the semiconductor device 120, the second facing region p2 includes a second element. The second element includes at least one selected from the group consisting of Mg, Zn and C. In this example, the second facing region p2 is a p-type region.

The first facing region p1 does not include the second element. Alternatively, a concentration of the second element in the first facing region p1 is lower than a concentration of the second element in the second facing region p2.

A higher threshold voltage can be obtained by providing the second facing region p2 of p-type. For example, a high threshold voltage can be stably obtained.

In the embodiment, at least one of the first electrode 51 and the second electrode 52 includes at least one selected from the group consisting of, for example, Ti, Al, Cu and Au. For example, the third electrode 53 includes at least one selected from the group consisting of TiN, WN, Ni, TaN, Ni, Au, Al, Ru, and W.

In the embodiment, the third electrode 53 may include, for example, conductive silicon or polysilicon. The third electrode 53 may include, for example, conductive poly-GaN or poly-AlGaN.

In the embodiment, the composition ratio x2 may be 1 or less. For example, the second semiconductor region 20 includes Alₓ₂Ga₁₋ₓ₂N (0<x2≤1, x1<x2). In the embodiment, the composition ratio x3 may be the composition ratio x2 or more. For example, the first film 41p contains Alₓ₃Ga₁₋ₓ₃N (0<x3≤1, x2≤x3).

As described above, the AlN layer may be provided between the first semiconductor region 10 and the second semiconductor region 20. The thickness of the AlN layer is, for example, 3 nm or less. By providing the AlN layer, for example, the mobility is improved. For example, the ON-resistance of the semiconductor device can be reduced.

For example, the nitride semiconductor layer 10B (see FIG. 1) may include a GaN layer including carbon. The concentration of carbon in the GaN layer including carbon is higher than the concentration of carbon in the first semiconductor region 10. Leakage current can be suppressed.

In the embodiment, when the distance d1 (see FIG. 1) is 100 nm or more, for example, the short channel effect is unlikely to occur.

In one example of the method for manufacturing the semiconductor device 110, as described above, a recess is formed in the stacked body that does not include the n-type region, and the n-type region may be formed in a part of the first semiconductor region 10. The n-shaped region can be formed, for example, by ion implantation. When forming the n-type region in a part of the first semiconductor region 10, the first element may also be included in a part of the first semiconductor portion 21. For example, the concentration of the first element in a part of the first semiconductor portion 21 may be higher than the concentration of the first element in the second semiconductor portion 22. As a result, the process margin can be widened. It is easy to obtain a semiconductor device with stable characteristics. After that, the insulating film is formed as described above, and the first to third electrodes 51 to 53 are formed. The semiconductor device 110 can also be formed by such a method.

In the semiconductor device 112 (see FIG. 5), the thickness of the third compound region 45c along the second direction D2 may be thicker than the thickness of the first compound region 45a along the first direction D1. The thickness of the third compound region 45c along the second direction D2 may be thicker than the thickness of the second compound region 45b along the first direction D1. The thick third compound region 45c provides, for example, a high carrier concentration. Easy to get low on resistance. A high threshold voltage can be stably obtained. Easy to obtain high reliability.

In the semiconductor device 112b (see FIG. 7), the first semiconductor portion 21 in contact with the fourth partial region 14 may include the first element. For example, the concentration of the first element in the first semiconductor portion 21 may be higher than the concentration of the first element in the second semiconductor portion 22. As a result, the process margin can be widened. It is easy to obtain a semiconductor device with stable characteristics.

In the semiconductor device 113 (see FIG. 8), the large first angle θ1 stabilizes the coverage of the first insulating region 41a, for example. For example, it is easy to obtain a uniform film.

Information on thickness and shape can be obtained, for example, by observing with an electron microscope. Information on the composition can be obtained by SIMS (Secondary Ion Mass Spectrometry) or EDX (Energy dispersive X-ray spectroscopy).

According to the embodiment, it is possible to provide a semiconductor device whose characteristics can be improved.

In the specification, “a state of being electrically connected” includes a state in which multiple conductors physically contacts and a current flows between the multiple conductors. “The state of being electrically connected” includes a state in which another conductor is inserted between the multiple conductors and a current flows between the multiple conductors.

In the present specification, “vertical” and “parallel” include not only strict vertical and strict parallel, but also variations in the manufacturing process, for example, and may be substantially vertical and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, semiconductor regions, nitride members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1-5. (canceled)

6. A semiconductor device, comprising:
a first electrode;
a second electrode, a direction from the first electrode to the second electrode being along a first direction;
a third electrode, a position of the third electrode in the first direction being between a position of the first electrode in the first direction and a position of the second electrode in the first direction;
a semiconductor member including a first semiconductor region and a second semiconductor region,
the first semiconductor region including Alₓ₁Ga₁₋ₓ₁N (0≤x1<1), the first semiconductor region including a first partial region, a second partial region, a third partial region, a fourth partial region, and a fifth partial region, a direction from the first partial region to the first electrode being along a second direction crossing the first direction, a direction from the second partial region to the second electrode being along the second direction, a direction from the third partial region to the third electrode being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction,
the second semiconductor region including Alₓ₂Ga₁₋ₓ₂N (0<x2≤1, x1<x2), the second semiconductor region including a first semiconductor portion, and a second semiconductor portion, a direction from the fourth partial region to the first semiconductor portion being along the second direction, a direction from the fifth partial region to the second semiconductor portion being along the second direction; and
a first insulating member including a first insulating region, a second insulating region, and a third insulating region, the first insulating region being between the fourth partial region and the third electrode in the first direction, the second insulating region being between the third electrode and the fifth partial region in the first direction, the third insulating region being between the third partial region and the third electrode in the second direction; and
a compound member including Alₓ₃Ga₁₋ₓ₃N (0<x3≤1, x2≤x3), the compound member including a first compound region and a second compound region, the first compound region being between the fourth partial region and the first insulating region in the first direction, the second compound region being between the second insulating region and the fifth partial region in the first direction,
the fourth partial region including a first facing region, the first facing region being in contact with the first compound region,
the fifth partial region including a second facing region, the second facing region being in contact with the second compound region,
the first facing region including a first element, the first element including at least one selected by the group consisting of Si, Ge, Te and Sn,
the second facing region not including the first element, or a concentration of the first element in the second facing region being lower than a concentration of the first element in the first facing region,
wherein
the second facing region includes a second element including at least one selected from the group consisting of Mg, Zn and C, and
the first facing region does not include the second element, or a concentration of the second element in the first facing region is lower than a concentration of the second element in the second facing region.

7. The device according to claim 6, wherein
the compound member further includes a third compound region, the third compound region being between the third partial region and the third insulating region in the second direction.

8. The device according to claim 7, wherein
the third partial region includes a third facing region,
third facing region is in contact with the third compound region, and
at least a part of the third facing region includes the first element.

9. The device according to claim 6, further comprising a second insulating member, the second insulating member including silicon and nitrogen,
the second insulating member includes a first insulating portion and a second insulating portion,
the first semiconductor portion is between the fourth partial region and the first insulating portion in the second direction, and
the second semiconductor portion is between the fifth partial region and the second insulating portion in the second direction.

10. The device according to claim 9, wherein
the first insulating member includes silicon and oxygen,
the first insulating member does not include nitrogen, or a concentration of nitrogen included in the first insulating member is lower than a concentration of nitrogen included in the second insulating member, and
the second insulating member does not include oxygen, or a concentration of oxygen included in the second insulating member is lower than a concentration of oxygen included in the first insulating member.

11. The device according to claim 6, wherein a distance between the first electrode and the third electrode along the first direction is shorter than a distance between the third electrode and the second electrode along the first direction.

12. The device according to claim 6, wherein a distance between the first electrode and the third electrode along the first direction is longer than a distance between the third electrode and the second electrode along the first direction.

13. The device according to claim 6, wherein
the third partial region includes a first surface,
the first surface faces the third insulating region,
the second semiconductor portion includes a second surface and a third surface,
the third surface faces the fifth partial region,
the second surface is on an opposite side of the third surface in the second direction, and
a distance between the first surface and the second surface along the second direction is not less than 100 nm and not more than 400 nm.

14. The device according to claim 6, wherein
the third partial region includes a first surface facing the third insulating region,
the fourth partial region includes a first side surface facing the first insulating region,
the fifth partial region includes a second side surface facing the second insulating region,
an angle between the first surface and the first side surface is larger than an angle between the first surface and the second side surface.

15. The device according to claim 6, wherein
the third partial region includes a first surface facing the third insulating region,
the fifth partial region includes a second surface facing the second insulating region, and
an angle between the first surface and the second surface is not less than 70 degrees and not more than 110 degrees.

16. The device according to claim 6, wherein at least a part of the first partial region includes the first element.

17. The device according to claim 6, wherein
the third electrode includes a first end portion and a second end portion,
a position of the first end portion in the first direction is between a position of the first electrode in the first direction and a position of the second end portion in the first direction,
the first end portion is between the fourth partial region and the fifth partial region in the first direction, and
a position of the second semiconductor portion in the second direction is between a position of the first end portion in the second direction and a position of the second end portion in the second direction.

18. The device according to claim 6, wherein a concentration of the first element in the first facing region is not less than 1×10¹⁶ cm⁻³ and not more than 5×10¹⁹ cm⁻³.
